(19) United States
(12) Patent Application Publication
(10) Pub. No.: US 2023/0299222 A1
(43) Pub. Date: Sep. 21, 2023

(54) POLYMERIC SOLAR PANEL BACKSHEETS AND METHOD OF MANUFACTURE

(71) Applicant: TOMARK-WORTHEN, LLC, Chadds Ford, PA (US)

(72) Inventors: David E. SANTOLERI, Chadds Ford, PA (US); Christopher THELLEN, Amherst, NH (US); Andreas ROTHACKER, Mont Vernon, NH (US)

(21) Appl. No.: 18/017,333

(22) PCT Filed: Jul. 21, 2021
(86) PCT No.: PCT/US2021/042665

§ 371 Date: Jan. 20, 2023

Related U.S. Application Data
(63) Continuation of application No. 17/382,176, filed on Jul. 21, 2021.
(60) Provisional application No. 63/054,776, filed on Jul. 21, 2020.

(51) Int. Cl. H01L 31/049; H01L 31/048; B32B 27/32; B32B 27/34; B32B 27/20; B32B 27/08

(52) U.S. Cl. CPC H01L 31/049; H01L 31/0481; B32B 27/32; B32B 27/34; B32B 27/20; B32B 27/08; B32B 2264/1027; B32B 2457/12; B32B 2270/00; B32B 2250/40

(57) ABSTRACT

An improved backsheet used in the construction of solar panels is disclosed. A method of manufacturing the backsheet and solar panel comprising the backsheet are also disclosed. Additionally, a photovoltaic solar panel module comprising the backsheet is disclosed. The backsheet may comprise a polymeric material that is produced in such a way that multiple functionalities are imparted into the material for outstanding performance and endurance in a solar module. The invention is further directed to a method for producing backsheets comprising such polymeric materials, and a solar cell incorporating such a backsheet. The backsheet may comprise a mono layer or multilayers in various embodiments. The backsheets improve upon the efficiency, strength, weather resistance, cost, and useful life of the solar panels in which the backsheets are incorporated.

### CROSS-REFERENCE TO RELATED APPLICATION

This application claims priority and benefit from U.S. Provisional Application Ser. No. 63/054,776, filed Jul. 21, 2020, and U.S. patent application Ser. No. 17/382,176, filed Jul. 21, 2021, the contents of each of which are incorporated by reference herein in their entireties.

### FIELD OF THE INVENTION

This invention is directed to a backsheet used in the construction of photovoltaic solar panels. More specifically, this invention is directed to a backsheet comprising a polymeric material that is produced in such a way that multiple functionalities are imparted into the material for outstanding performance and endurance in a solar module. The invention is further directed to a method for producing backsheets comprising such polymeric materials, and a solar cell incorporating such a backsheet.

### BACKGROUND OF THE INVENTION

Photovoltaic solar panels modules on the market today typically comprise a front cover, a first layer of encapsulant, one or more photovoltaic (“PV”) cells, a second layer of encapsulant, and a layer of insulation adjacent to the second layer of encapsulant on the backside of the solar panel module. The insulation layer is intended to provide electrical insulation for safety, and prevent performance problems such as current leakage or potential short circuits. This insulation layer is generally referred to in the trade as a “backsheet.”

Over the past several decades, this insulation layer, or backsheet, has been primarily constructed as a three layer laminate structure that utilizes: (i) a fluoropolymer exterior layer; (ii) a bi-axially oriented polyester (hereinafter “PET”) core layer; and (iii) either another fluoropolymer layer, or an olefin adhesive layer such clarified polyethylene (hereinafter “PE”) or ethylene vinyl acetate (hereinafter “EVA”) film. This type of backsheet construction is depicted in FIG. 1.

The function of the fluoropolymer layer is solely to provide long term ultraviolet (“UV”) protection of the internal PET layer. Fluoropolymers are well known to provide excellent outdoor weather resistance and long term durability. However, fluoropolymers are fairly expensive components, and under most conditions the useful life of the fluoropolymer layer will far exceed the life of the solar panel.

The PET core layer of the typical backsheet serves two functions: (i) providing excellent insulation characteristics; and (ii) providing excellent dimensional stability. Both properties are critical to successful backsheet performance and need to be maintained over the life of the panel.

The third layer of the current backsheet also provides several functions: (i) it enables a durable bond between the module encapsulant material and the backsheet; (ii) it provides enhanced reflectivity to improve the solar panel module efficiency; and (iii) it also serves as part of the total laminate dielectric material.

Historically the backsheet described above has been made with individual films that are laminated together with various adhesives. The adhesive selection is critical as it has proven to be one of the major weak links in the backsheet and module structure, causing inter layer adhesion issues in the field. Recently the fluoropolymer exterior layer has been applied using a fluoropolymer coating instead of the traditional film. This approach has proven to have two major advantages: first the elimination of one adhesive layer; and, second, the ability to reduce the fluoropolymer layer thickness, thereby reducing the overall cost of manufacturing the solar panel module.

It should be noted, however, that the PET layer, while being an excellent insulator with good dimensional stability, does have some negative characteristics. PET has both poor UV resistance and hydrolysis resistance, which often results in premature failure of the backsheet.

Recently, however, the introduction of backsheets using a PET exterior layer has captured significant market share. These backsheets are made with a special PET exterior layer that has been modified to improve both UV properties and reduce hydrolysis concerns. The interior layer used the same unmodified PET used in the fluoropolymer-based backsheets along with the same olefin adhesive layer. The result is a fairly low cost backsheet that may be adequate when used in some applications. However, this construction is also made with adhesive layers and is subject to interlayer adhesion failures. Even though the PET exterior layer may be modified to perform better than an unmodified PET layer, the reality is that this backsheet is likely to prove to be unsatisfactory over time.

More recently, backsheets based on polyamides have been introduced to the solar panel market. The initial products introduced to the market were based on various layers of polyamides, with the exterior layers being modified with UV absorbers and fillers to provide some facsimile of UV stability. In general, polyamide is not considered for exterior applications due to poor UV stability. These constructions were made with the same lamination process found in other backsheets and are also subject to interlayer adhesion issues. In this regard, long chain polyamides are generally required in backsheet application due to the fact that shorter chain nylons absorb moisture more readily than the long chain polyamides. Short chain nylons can usually absorb up to about 6.5% moisture, which moisture could adversely affect the electrical insulation properties of the backsheet. Although long chain nylons may perform better with the best absorbing only about 2% moisture, long chain nylons are very expensive and add significant cost to the backsheet.

Accordingly, solar panel backsheets currently in use today exhibit several characteristics which leave room for improvement. First, the use of a fluoropolymer layer is costly and is over-engineered in typical solar panel applications. Secondly, on the opposite side of the spectrum, the modified PET or modified polyamide is a high risk for use in the PV system, since it will fail prematurely in many applications causing panels to potentially be unsafe and inefficient. Additionally, a solar panel system that incorporates the use of adhesives is prone to problems in manufacturing as well as subject to premature failure in the field.

In addition, early embodiments of polypropylene-based backsheets have exhibited limitations in the use of such materials including low continuous use temperatures, poor UV resistance and low thermal degradation temperatures along with poor adhesion to other materials such as PV encapsulants. Certain limitations and shortcomings of polyolefins have generally stemmed from lack of polar functionality and structure diversity, which have been compounded with the long-standing challenges in the chemical modification and/or functionalization of polyolefins.

Among the polyolefins, polypropylene is one polymer which has exhibited promise in PV applications due to its potential low cost but is also one of the more difficult materials to be functionalized by both direct and post-polymerization processes. As the industry develops technology to increase the throughput and speed of module manufacturing through higher temperature processes, polyolefin materials, such as polyethylene and polypropylene, run the risk of problems at these higher temperatures due to low melting points as well as mechanical degradation at elevated temperatures. See generally “Polyolefin Backsheets Taking Confident First Steps,” PV Magazine, Issue 11, Nov. 7, 2017.

Thus, there exists a need for an efficient, durable, weather resistant, and cost effective backsheet used in the construction of solar panel systems. Further, the need exists for a solar panel backsheet which utilizes less expensive polymeric materials such as polyethylene and polypropylene. There also exists a need for a solar panel backsheet which eliminates the use of adhesives in the backsheet construction. The need also exists for an efficient and cost-effective method for manufacturing such improved solar panel backsheets.

### SUMMARY OF THE INVENTION

The need for providing an efficient, durable, weather resistant, and cost effective backsheet which utilizes less expensive polymeric materials such as polyethylene and polypropylene and/or eliminates the use of adhesives used in the construction of photovoltaic solar panel systems is achieved by the backsheet and of this invention. Moreover, the need for providing an efficient method for manufacturing such improved solar panel backsheets, is also achieved by the method of this invention.

In one embodiment, the backsheet disclosed herein may include a new functional polyolefin system in which diverse polymer structures may now be manufactured economically through reactive compounding to meet the requirements of many important industrial applications. Products and materials having the generic structure depicted in FIG. 2 are now available commercially to match various application and processing requirements.

The polyolefin component depicted in FIG. 2, which may be utilized as a component in the construction of one embodiment of the photovoltaic backsheet disclosed herein, comprises multiple polar functionalities which are segments of the polyolefin molecules themselves. Said functionalities may include hindered phenol antioxidants, hydroxyl groups, UV-resistant chemistries, flame retardants, antimicrobial additives and maleic anhydride species. These functionalities may be produced at the raw material supplier through simultaneous chemical attachment directly to the polyolefin chains during polymerization or through reactive extrusion. The resulting multi-functional polyolefins may exhibit unique properties beyond existing similarly modified polyolefins. These properties may include, but are not limited to, stability to UV radiation, thermal stability, flame retardancy and resistance to organic solvents.

Some of the key benefits of the polyolefin depicted in FIG. 2 include:

1. Enhanced Use and Processing Temperatures.

Increase the operating temperature of respective Polyolefins with the chemically attached hindered phenol (HP) groups. For PP, this means an increase of the continuous use temperature from about 70 to about 110° C. for a typical commercial PP to about 130° C. to about 160° C. With proper heat treatment at sufficient HP composition, this PP-HP can be used at up to about 190° C. with short term thermal stability over about 300° C. This also enables proprietary compounding with other high temperature polymer systems that require processing temperatures above about 300° C.

FIG. 3 depicts an improvement by the bonded HP and dependence on HP composition. A predefined degradation temperature (T_{d}, on-set degradation defined as temperature at about 5% weight loss in TGA curve running in air at about 10° C. per hr.). Note that T_{d} may be a good indicator of overall thermal stability as it has been shown to be consistent with other evaluating techniques.

2. Reliable Crosslinking Mechanism for Improvement in Various Properties.

HP or other potential function group can be used as crosslink points with heat treatment or chemical agents.

3. Adhesion to Other Substrate that is Difficult by Polyolefins.

Either -MA, —OH or —NH2 groups can be used to modify the surface properties of Polyolefins to different substrates, at various concentration levels. It can also be used to modify the hydrophobic behavior of Polyolefins as needed.

4. Compatibilizer for Compounds, Blends or Alloys.

The attached functional group can be used to improve interface with filler such as various Nano-particles, CN tubes, Graphene, minerals, glass fiber, carbon fiber compounds. It may also enable the blending with traditionally incompatible polar materials and possibly even forming miscible alloys.

5. Electrical and Dielectric Enhancement.

The electric or dielectric properties can be further improved with the attachment of proper functional group(s) or copolymer(s).

6. UV Resistance.

Additives known to be effective in protecting polyolefins from UV degradation can be directly attached to the polymer to provide superior protection from UV radiation. This high molecular weight species prevents migration resulting in better additive effectiveness.

7. Antimicrobial Properties.

Additives known to be effective in protecting polyolefins from microbial attack can be directly attached to the polymer to provide antimicrobial properties.

The backsheets disclosed herein may be used in connection with photovoltaic solar panel modules. Such photovoltaic solar panel modules may comprise a front cover having inner and outer surfaces, and one or more photovoltaic cells substantially encapsulated in an encapsulant having a top outer surface and a bottom outer surface. The top outer surface of the encapsulant may be adjoined, adhered, or affixed to the inner surface of the front cover, and the bottom outer surface of the encapsulant may be adjoined, adhered, or affixed to the inner surface of the interior layer of the backsheet.

### BRIEF DESCRIPTION OF THE DRAWINGS

Understanding of the present invention will be facilitated by consideration of the following detailed description of the embodiments of the present invention taken in conjunction with the accompanying drawings, in which like numerals refer to like parts, and wherein:

FIG. 1 is a cross sectional schematic of the layers of a prior art embodiment of a solar panel backsheet.

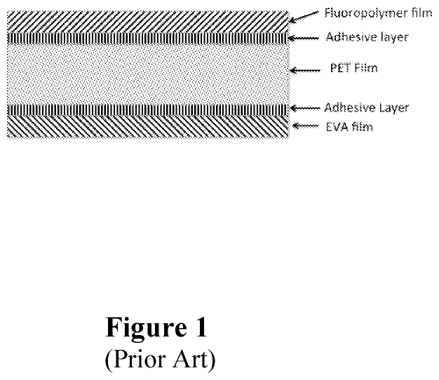

FIG. 2 is a schematic of a polyolefin molecule with multiple functionalities which may be utilized in one embodiment of the solar panel backsheet.

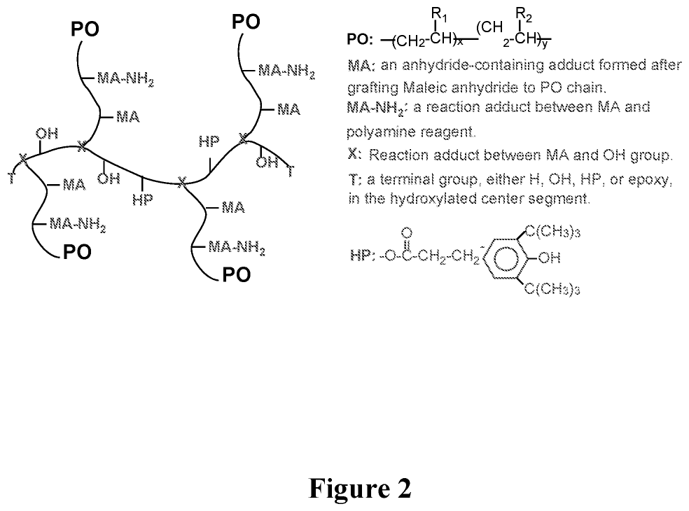

FIG. 3 is a depiction of TGA Curves of Reactive Compounded PP-HP with different HP composition, TGA runs at a rate of about 10° C./min in air.

FIG. 4 is a cross sectional schematic of a mono-layered or single layer backsheet comprising a functionalized Polyolefin layer of one embodiment of the solar panel backsheet.

FIG. 5 is a block diagram depicting one embodiment of a method of manufacturing the solar panel backsheet via a cast film process.

FIG. 6 is a cross sectional schematic depicting a solar cell construction incorporating one embodiment of the solar panel backsheet.

FIG. 7 is a block diagram depicting one embodiment of a method of manufacturing the backsheet via a blown film process.

FIGS. 8A and 8B are cross sectional schematics of two-layer embodiments for functionalized polyolefin solar panel backsheets.

FIGS. 9A and 9B are cross sectional schematics of multi-layer embodiments of solar panel backsheets with low temperature polyolefin bonding layers on the cell side.

FIG. 10 is a cross sectional schematic of a five-layered embodiment of the solar panel backsheet.

FIG. 11 is a cross sectional schematic of a three-layered embodiment of the solar panel backsheet.

FIG. 12 is a cross sectional schematic of a five-layered embodiment of the solar panel backsheet.

FIG. 13 is a cross sectional schematic of a three-layered embodiment of the solar panel backsheet.

FIG. 14 is a cross sectional schematic of a monolayered embodiment of the solar panel backsheet.

FIG. 15 is a cross sectional schematic of a two-layered embodiment of the solar panel backsheet.

### DETAILED DESCRIPTION OF THE EMBODIMENTS

It is to be understood that the figures, images and descriptions of the present invention have been simplified to illustrate elements that are relevant for a clear understanding of the present invention, while eliminating, for the purposes of clarity, many other elements which may be found in the present invention. Those of ordinary skill in the pertinent art will recognize that other elements are desirable and/or required in order to implement the present invention. However, because such elements are well known in the art, and because such elements do not facilitate a better understanding of the present invention, a discussion of such elements is not provided herein.

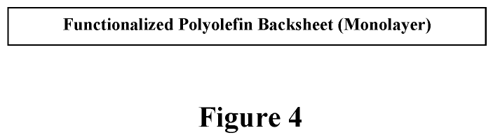

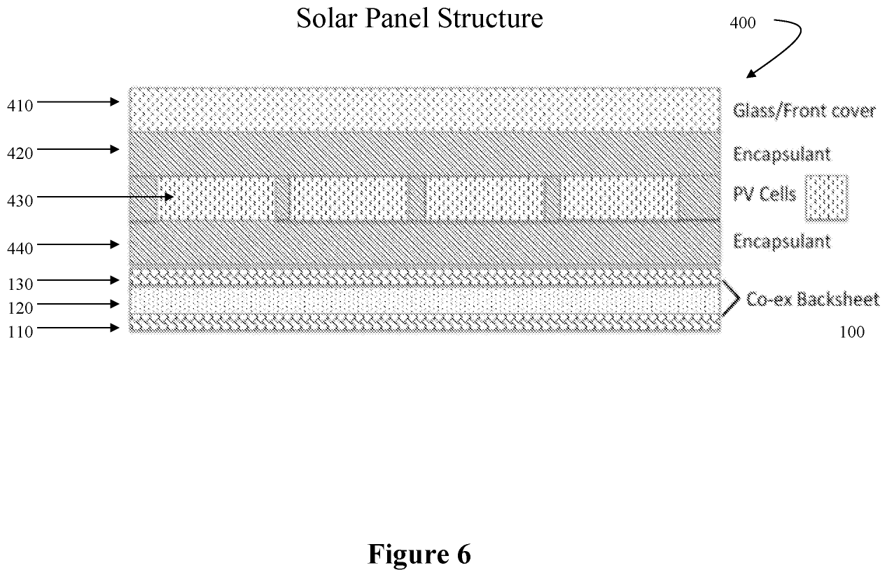

Turning now to FIG. 4, there is shown a cross sectional schematic of backsheet 400 of one embodiment of the instant invention. Backsheet 400 may comprise a single or mono layer 410 having inner and outer surfaces. In this one embodiment of backsheet 400, inner surface of layer 410 may be adjoined, adhered, or affixed to an outer surface of a solar cell (see for example the backsheet/cell structure of FIG. 6 where backsheet 400 could replace co-extruded backsheet comprising layers 110, 120, and 130). Co-extrusion processes may also be employed in the adjoining, adherence, and/or affixation of backsheet 400 to a solar cell.

In the embodiment shown in FIG. 4, a monolayer backsheet structure may be produced using the functionalized polyolefin in the entire construction. The polyolefin contains multiple polar functionalities which are segments of the polyolefin molecules themselves. Said functionalities may include hindered phenol antioxidants, hydroxyl groups, UV-resistant chemistries, and maleic anhydride species. These functionalities are produced at the raw material supplier through simultaneous chemical attachment directly to the polyolefin chains during polymerization or through reactive extrusion. The resulting multi-functional polyolefins exhibit unique properties beyond existing similarly modified polyolefins. These properties may include, but are not necessarily limited to, stability to UV radiation, thermal stability, flame retardancy and resistance to organic solvents. This construction may provide proper bonding to the encapsulant of choice and may contain the necessary functionalities in a single layer. In this embodiment of backsheet 400, the polyolefin may obtain a relative thermal index (RTI) of about 90° C. or higher in order to generally meet relied upon insulation requirements for solar modules. At the time of this disclosure, the minimum thickness of RTI rated material is about 6.0 mil for 1000V modules and about 12.0 mil for 1500V modules. Therefore, the total thickness of this backsheet may be between about 6.0 mil and about 12.0 mil, depending on the voltage rating of the module.

Backsheet 400 of the instant invention eliminates many of the deficiencies found in known laminated backsheets while reducing the overall cost of producing backsheet 400. Backsheet 400 of this invention utilizes materials which are more cost effective than fluoropolymers used in the exterior layer of known backsheets, and provide better weather resistant properties than those of PET. Moreover, backsheet 400 of this invention is made with no interlayer adhesives.

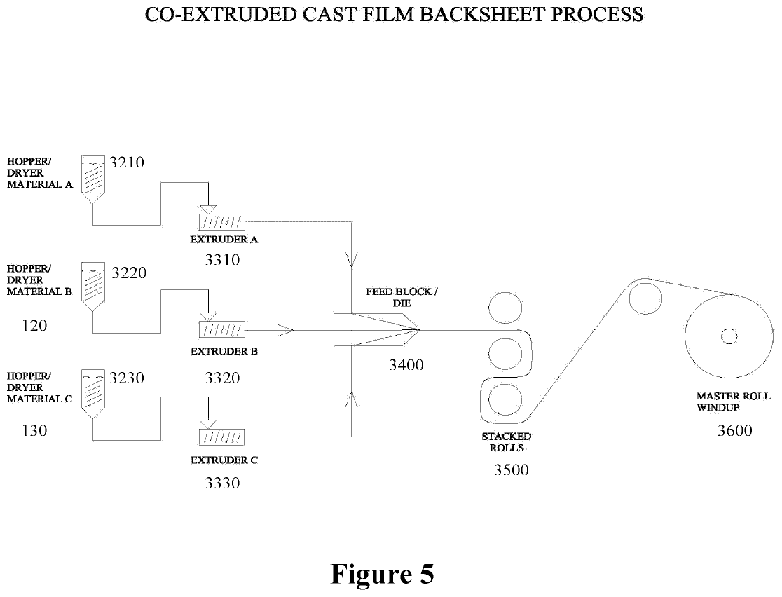

Turning now to FIG. 5, there is shown a block diagram depicting one embodiment of a method for manufacturing multi-layered backsheets disclosed herein which utilizes a co-extruded cast film process.

Other extrusion and/or non-adhesive lamination methods for producing the backsheets disclosed herein may also be employed such as, for example, blown film methodologies.

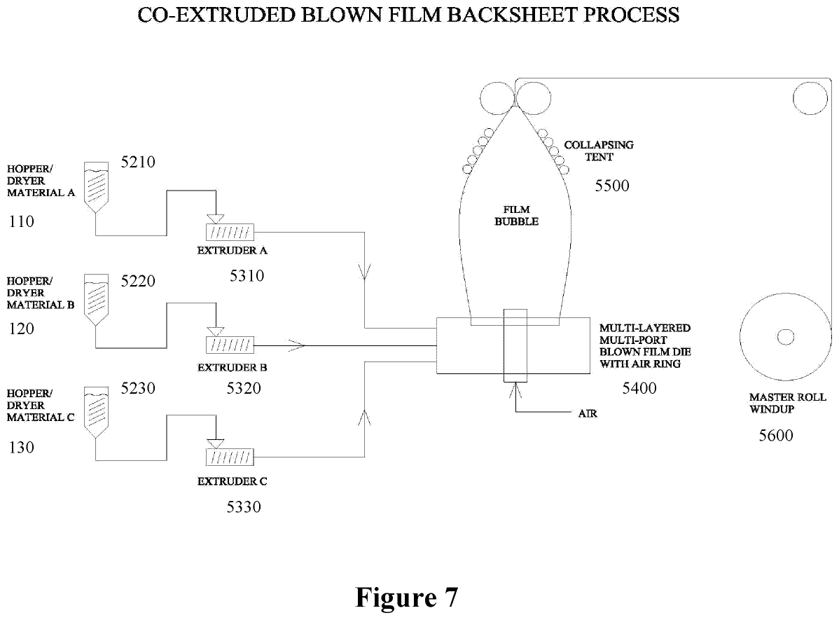

Turning now to FIG. 7, is shown a block diagram depicting another embodiment of a method for manufacturing multi-layered embodiments of the backsheets disclosed herein which utilize s a co-extruded blown film process.

Although it is preferred that the backsheets disclosed herein do not utilize adhesives for joining the backsheet layers together, it is possible to employ manufacturing processes which do utilize an amount of suitable adhesive between any two layers of various embodiments of the backsheets, if desired.

Turning now to FIG. 6, there is shown a cross sectional schematic depicting a solar cell construction 400 which incorporates one embodiment of the solar panel backsheet of the instant invention. Solar cell 400 comprises front cover 410, photovoltaic cells 430 encapsulated in one or more suitable encapsulants 420 and 440, which comprises top encapsulant portion 420 and bottom encapsulant portion 440, and backsheet 100. The backsheets disclosed herein may be substituted for backsheet 100 as depicted in FIG. 6.

In FIG. 6, front cover 410 may be constructed from glass or any other suitable material which transmits light to PV cells 430. Encapsulant portions 420 and 440 may comprise a single unitary construction, or may comprise separate encapsulant portions 420 and 440 joined together to encapsulate PV cells 430. Encapsulant portions 420 and 440 may further comprise the same or different material or materials. In one embodiment, top encapsulant portion 420 may comprise a material which protects PV cells 430 but, like front cover 410, also transmits light to PV cells 430. In addition, bottom encapsulant portion 440 may comprise a material which also protects PV cells 430 but also either reflects or absorbs light in a manner which improves the efficiency of PV cells 430.

In the embodiment of solar cell 400 depicted in FIG. 6, PV cells 430 are substantially encapsulated in encapsulant 420 and/or 430. The outer surface of encapsulant portion 420 is adjoined, adhered, or affixed to the inner surface of front cover 410. The outer surface of encapsulant portion 440 is adjoined, adhered, or affixed, or otherwise affixed to, the inner surface of backsheet interior layer 130.

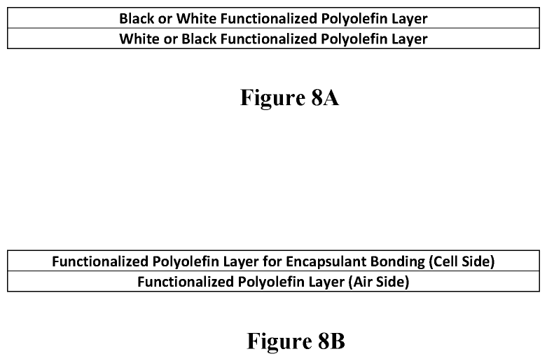

In other embodiments of the backsheets disclosed herein, FIGS. 8A and 8B depict multi-layer structures which may be produced using the Hindered-Phenol Polyolefin material described herein. There are several advantages to a multi-layer structure using this polymer. Such advantages may include, but are not limited to, the following:
1. The incorporation of up to about 15% carbon black in one layer and up to about 50% titanium dioxide in an additional layer in order to produce a backsheet construction with both a “black” and “white” side. One advantage of this design may be to provide an aesthetically pleasing “black” color on the cell-side of the module, and a cooling “white” layer on the back-facing side of the module.
2. Incorporation a maleic anhydride species in only the “interior” layer of the backsheet may promote adhesion to the module encapsulant. In such an embodiment, maleic anhydride may not be needed on the backside of the backsheet and therefore, may create a two-layer construction which may save costs.

As indicated in other embodiments disclosed herein, the thickness of the individual layers may be based upon the RTI rating of the material used in those layers and the voltage requirements for the module that the backsheet may be used in.

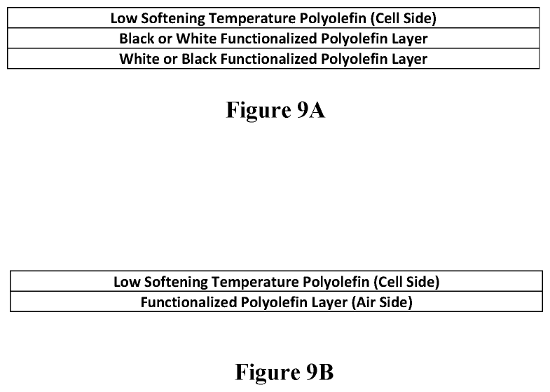

FIGS. 9A and 9B depict yet other embodiments of a multi-layered backsheet which may include a multi-layer backsheet, wherein the layers described above may be affixed, adjoined or adhered to an alternative polyolefin polymer such as HDPE or LDPE, to enable lower temperature lamination temperatures at the module manufacturing operation.

Photovoltaic solar panels modules on the market today typically comprise a front cover, a first layer of encapsulant, one or more photovoltaic cells, a second layer of encapsulant, and a layer of insulation adjacent to the second layer of encapsulant on the backside of the solar panel module. The insulation layer is intended to provide electrical insulation for safety, and prevent performance problems such as current leakage or potential short circuits. This insulation layer is generally referred to in the trade as a “backsheet.”

Although the backsheet described is intended to be produced through co-extrusion methods for cost savings purposes, it could also be produced through a lamination procedure where each layer is produced individually and then laminated together in a secondary process through solvent, 100% solids or water-based adhesives.

An additional alternative would be a backsheet construction in which the hindered-phenol polyolefin is used as a layer in the backsheet that is applied to a non-polyolefin layer such as metal (aluminum foil, copper, etc.) or a different family of polymers (polyamides, polyesters, polycarbonates, fluoropolymers, etc.). This type of backsheet could be produced as a co-extruded product or through a lamination process.

One feature of the backsheets disclosed herein may be the use of the multi-functional polyolefin material described herein in a photovoltaic backsheet. As mentioned, polyolefin based backsheets are seeing greater interest in the photovoltaic market, but have temperature and stability limitations that are solved through the use of these functionalities that are built directly into the polymer. As described previously, earlier polyolefin backsheets use these functionalities through additives but struggle to achieve the durability needed for 30+ years of performance due to the deficiencies outlined herein.

5-Layer Symmetrical Backsheet

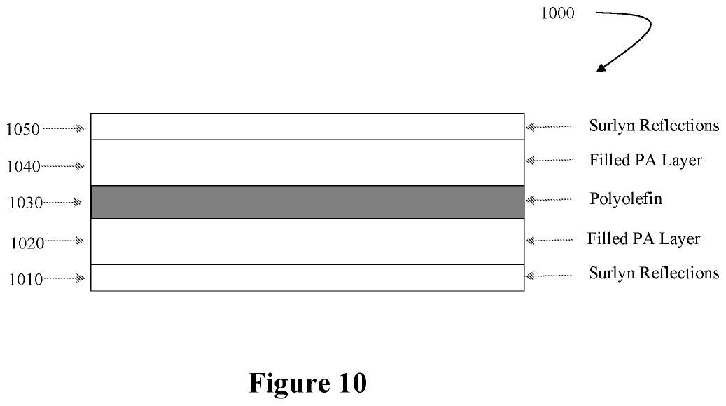

Turning now to FIG. 10, there is shown a cross sectional schematic of an embodiment of backsheet 1000. Backsheet 1000 may comprise exterior layer 1010 having inner and outer surfaces, exterior intermediate layer 1020 having inner and outer surfaces, middle layer 1030 having inner and outer surfaces, interior intermediate layer 1040 having inner and outer surfaces, and interior layer 1050 having inner and outer surfaces.

In one embodiment of backsheet 1000, the outer surface of middle layer 1030 may be adjoined, adhered, or affixed to the inner surface of intermediate exterior layer 1020, and the inner surface of middle layer 1030 may be adjoined, adhered, or affixed to the outer surface of intermediate interior layer 1040. The inner surface of exterior layer 1010 may be adjoined, adhered, or affixed to the outer surface of intermediate exterior layer 1020, and the outer surface of interior layer 1050 may be adjoined, adhered, or affixed to the inner surface of intermediate interior layer 1040.

Backsheet 1000 may be adjoined, adhered, or affixed to a solar panel module by adjoining, adhering, or affixing the inner surface of interior layer 1050 or the outer surface of exterior layer 1010 to the outer surface of the solar panel module.

In one embodiment, exterior layer 1010, exterior intermediate layer 1020, middle layer 1030, interior intermediate layer 1040, and interior layer 1050 may be adjoined, adhered, or affixed via a co-extrusion process therein eliminating the need for the use of adhesives for bonding the layers of backsheet 1000 together.

Co-extrusion processes which may be utilized for manufacturing backsheet 1000 may be similar to the co-extrusion processes shown and described in connection with FIGS. 5 and 7, except that backsheet 1000 may comprise five layers rather than the three layer construction depicted in FIGS. 5 and 7. Optimal methods employed in the co-extrusion manufacturing processes used to manufacture backsheet 1000 may vary depending upon the specific material compositions comprising the various layers of backsheet 1000, thicknesses of the various layers of backsheet 1000, as well as the temperature, pressure, dwell times, machine speed, and/or other variables associated with the specific apparatus utilized in the manufacture of backsheet 1000.

Backsheet 1000 may eliminate many of the deficiencies found in known laminated backsheets while reducing the overall cost of producing backsheet 1000. Backsheet 1000 may utilize materials which are more cost effective than fluoropolymers used in the exterior layer of known backsheets, and provide better weather resistant properties than those of PET. Moreover, backsheet 1000 may be made with no interlayer adhesives.

In yet another embodiment of backsheet 1000, exterior layer 1010 of backsheet 1000 may comprise Surlyn Reflections™. Surlyn Reflections™ is a polyamide and ionomer alloy available through DuPont, has been manufactured under license from DuPont by LTL compounders in Morrisville, Pa., and is generally described in further detail above.

In addition, exterior layer 1010 comprising Surlyn Reflections™ may be pigmented to provide any color desired, such as white or black depending on where the solar panel is being deployed and whether or not additional absorption or reflection is desired. Compatiblized alloys of other lower cost olefins such as polyethylene or polypropylene may also be utilized, however, the ionomer offers advantages in the adhesion of junction boxes to the backsheet and higher temperature stability. In one embodiment of backsheet 1000, exterior layer 1010 may comprise black Surlyn Reflections™.

One or more of exterior intermediate layer 1020 and interior intermediate layer 1040 may comprise a talc filled polyamide (hereinafter “PA”). PA610, PA612, PA11, PA12, PA9T, PA6, PA6G, and PA66 all may be acceptable alternative materials to be used for one or more of exterior intermediate layer 1020 and interior intermediate layer 1040. One of the materials which may be used as exterior intermediate layer 1020 and/or interior intermediate layer 1040 may comprise either PA612, due to its low cost, or PA610, due to it being a bio-based, renewable and environmentally friendly polymer material, also of relatively low cost. In one embodiment, PA610 may comprise up to about sixty-five percent (65%) renewable materials. In one such embodiment of PA610, such renewable materials may be derived from castor bean oil.

Exterior intermediate layer 1020 and interior intermediate layer 1040 may also provide excellent dielectric properties, dimensional stability and higher temperature functionality than known backsheets. The nylons can be filled between about ten percent (10%) and about forty percent (40%) with talc, with the one loading being about twenty-five percent (25%).

Middle layer 1030 may comprise a polyolefin. Middle layer 1030 may also comprise a maleic anhydride species which may enhance the bonding of intermediate layers 1020 and 1040 comprising a polyamide to middle layer 1030 comprising a polyolefin during the fabrication process of backsheet 1000. The fabrication process of backsheet 1000 may comprise co-extrusion and/or lamination processes.

Like exterior layer 1010, interior layer 1050 of backsheet 1000 may also comprise polyamide and ionomer alloy layer, such as Surlyn Reflections™. In general, the layer facing the PV cells provides for more efficient operation in the solar panel module when interior layer 1050 has enhanced reflectivity. It has been an observed improvement in overall solar panel efficiency of up to about five percent (5%) over dark colored backsheets in certain embodiments of backsheet 1000.

In this regard, interior layer 1050 may comprise a highly reflective white polyamide and ionomer alloy layer, such as Surlyn Reflections™, which exhibits good bonding characteristics, and bonds particularly well to EVA encapsulant, providing bond strengths of over about 70 N/cm. Although interior layer 1050 may comprise a more traditional clarified PE or EVA, the use of a highly reflective, white, polyamide and ionomer alloy layer, such as Surlyn Reflections™, provides an interior layer 1050 that has a melting point above about one hundred fifty degrees Celsius (150° C.) and, therefore, does not ooze during the panel lamination process. In this regard, backsheets that incorporate an EVA layer are subject to the EVA layer flowing during the panel lamination inasmuch as EVA has a melting point below the typical about one hundred forty degrees Celsius (140° C.) to about one hundred fifty degrees Celsius (150° C.) typically used in panel lamination processes. In one embodiment of backsheet 1000, interior layer 1050 may comprise black Surlyn Reflections™.

In one embodiment, backsheet 1000 may be produced as a 5-layer structure as illustrated in FIG. 10. In this embodiment, the backsheet structure is similar to the embodiment depicted as coextruded backsheet 100 in FIG. 6, except that polyolefin layer 1030 is added as the middle layer of backsheet 1000, surrounded on each side with filled polyamide (PA) intermediate layers 1020 and 1040. Polyolefin middle layer 1030 may have a thickness of between about 1.0 mil and about 5.0 mils. PA intermediate layers 1020 and 1040 may have thicknesses of between about 2.0 mils and about 6.0 mils each. Polyolefin middle layer 1030 may contain a maleic anhydride species for bonding of polyamide intermediate layers 1020 and 1040 to polyolefin middle layer 1030 during the fabrication process of backsheet 1000. The fabrication process of backsheet 1000 may comprise co-extrusion and/or lamination processes.

Further in this embodiment, exterior layer 1010 and interior layer 1050 may comprise a PA-Ionomer, each of which may have a thickness of between about 1.0 mil and about 4.0 mils. Polyolefin middle layer 1030 may provide a moisture barrier capability to backsheet 1000 for reduction or elimination of moisture transmission through backsheet 1000 and into the solar module to which backsheet 1000 may be adjoined, adhered, or affixed. The addition of middle layer 1030 between intermediate layers 1020 and 1040 in backsheet 1000 also maintains symmetry in backsheet 1000 which may reduce curl and may also eliminate the chance of lamination errors in solar panel module manufacturing by allowing the module manufacturer to laminate either the inner surface of interior layer 1050 or the outer surface of exterior layer 1010 to a surface of the solar panel module.

Other than the thickness of polyolefin middle layer 1030, the thicknesses of the remaining layers of backsheet 1000 may be determined by the voltage rating required for the solar panel module. Presently, “relied upon insulation” refers to materials in the backsheet that have a relative thermal index (RTI) of about 90° C. or higher. Generally, 1000V rated solar panel modules require backsheets, such as backsheet 1000, to maintain a relied upon minimum insulation thickness of about 6.0 mil, and 1500V modules require a minimum insulation thickness of about 12.0 mil. In certain embodiments of backsheet 1000, PA intermediate layers 1020 and 1040 and PA-Ionomer alloy exterior and interior layers 1010 and 1050 meet this requirement for relied upon insulation, however, polyolefin middle layer 1030 may not. Therefore, the layer thicknesses may be primarily driven by this requirement for relied upon insulation along with the barrier performance provided by polyolefin middle layer 1030 as a thicker polyolefin middle layer 1030 may provide a better moisture barrier.

3-Layer Asymmetrical Backsheet

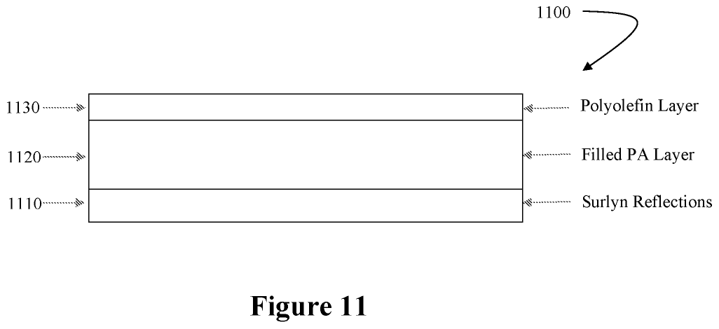

Turning now to FIG. 11, there is shown a cross sectional schematic of an embodiment of backsheet 1100. Backsheet 1100 may comprise exterior layer 1110 having inner and outer surfaces, middle layer 1120 having inner and outer surfaces, and interior layer 1130 having inner and outer surfaces.

In this embodiment of backsheet 1100, the outer surface of middle layer 1120 may be adjoined, adhered, or affixed to the inner surface of exterior layer 1110, and the inner surface of middle layer 1120 may be adjoined, adhered, or affixed to the outer surface of interior layer 1130. In one embodiment of backsheet 1100, exterior layer 1110, middle layer 1120, and interior layer 1130 may be adjoined, adhered, or affixed via a co-extrusion process therein eliminating the need for the use of adhesives for bonding the layers of backsheet 1100 together.

Co-extrusion processes which may be utilized for manufacturing backsheet 1100 may be similar to the co-extrusion processes shown and described in connection with FIGS. 5 and 7, except that backsheet 1100 may comprise different material compositions utilized in the layered construction of backsheet 1100. Optimal methods employed in the co-extrusion manufacturing processes used to manufacture backsheet 1100 may vary depending upon the specific material compositions comprising the various layers of backsheet 1100, thicknesses of the various layers of backsheet 1100, as well as the temperature, pressure, dwell times, machine speed, and/or other variables associated with the specific apparatus utilized in the manufacture of backsheet 1100.

Backsheet 1100 may eliminate many of the deficiencies found in known laminated backsheets while reducing the overall cost of producing backsheet 1100. Backsheet 1100 may utilize materials which are more cost effective than fluoropolymers used in the exterior layer of known backsheets, and provide better weather resistant properties than those of PET. Moreover, backsheet 1100 may be made with no interlayer adhesives.

In yet another embodiment of backsheet 1100, exterior layer 1110 of backsheet 1100 may comprise Surlyn Reflections™. Surlyn Reflections™ is a polyamide and ionomer alloy available through DuPont, has been manufactured under license from DuPont by LTL compounders in Morrisville, Pa., and is generally described in further detail above.

In addition, exterior layer 1110 comprising Surlyn Reflections™ may be pigmented to provide any color desired, such as white or black depending on where the solar panel is being deployed and whether or not additional absorption or reflection is desired. Compatiblized alloys of other lower cost olefins such as polyethylene or polypropylene may also be utilized, however, the ionomer offers advantages in the adhesion of junction boxes to the backsheet and higher temperature stability. In one embodiment of backsheet 1100, exterior layer 1110 may comprise black Surlyn Reflections™.

Middle layer 1120 may comprise a talc filled polyamide (hereinafter “PA”). PA610, PA612, PA11, PA12, PA9T, PA6, PA6G, and PA66 all may be acceptable alternative materials to be used for middle layer 1120. One of the materials which may be used as middle layer 1120 may comprise either PA612, due to its low cost, or PA610, due to it being a bio-based, renewable and environmentally friendly polymer material, also of relatively low cost. In one embodiment, PA610 may comprise up to about sixty-five percent (65%) renewable materials. In one such embodiment of PA610, such renewable materials may be derived from castor bean oil.

Interior layer 1130 may comprise a polyolefin. Interior layer 1130 may also comprise a maleic anhydride species which may enhance the bonding of middle layer 1120 comprising a polyamide to inner layer 1130 comprising a polyolefin during the fabrication process of backsheet 1100. The fabrication process of backsheet 1100 may comprise co-extrusion and/or lamination processes.

In one embodiment, backsheet 1100 may be produced as a 3-layer structure as illustrated in FIG. 11. In this embodiment, interior layer 1130, having an inner surface and an outer surface, may comprise a polyolefin layer. The inner surface of interior layer 1130 may be adjoined, adhered, or affixed to an outer surface of an encapsulant layer of a solar panel module. Interior layer 1130 may have a thickness of between about 1.0 mil and about 5.0 mil.

Also in this embodiment, middle layer 1120, having an inner surface and an outer surface, may comprise a polyamide layer and have a thickness of between about 4.0 mil and about 12 mil, depending upon the rating requirement of the solar panel module with which backsheet 1100 will be adjoined, adhered, or affixed.

Also, in this embodiment, exterior layer 1110, having an inner surface and an outer surface, may comprise a polyamide and ionomer alloy layer, such as Surlyn Reflections™, and have a thickness of between about 1.0 and about 4.0 mils. The configuration of this embodiment of backsheet 1100 may be designed to reduce distortion of the various backsheet 1100 layers during the lamination process caused by the potentially high shrinkage of the encapsulant layer used in the solar panel module to which backsheet 1100 is adjoined, adhered, or affixed.

In certain embodiments of the 3-layer design of backsheet 1100, a reduction and/or elimination of lamination defects (sometimes experienced with certain embodiments of the 5-layer backsheet 1000 design) may be realized. Such defects may be caused by shifting of a low-modulus interior layer 1130 and higher modulus outer layers, such as middle layer 1120 and/or exterior layer 1110, at temperatures seen by backsheet 1100 when being laminated to a solar panel module. Nevertheless, 5-layer backsheet 1000 embodiments are still suitable for defect-free laminations when a low-shrinkage solar panel module encapsulant is used in the lamination process.

The three-layer backsheet 1100 design also allows for one or more colored interior layer 1130 and/or exterior layer 1110 (such as, for example. black and/or white colors) when the number of extruders available in the co-extrusion process is limited to three or less.

Polyamide-Polyolefin Alloy Outer Layer with Hindered-Phenol Polyolefins

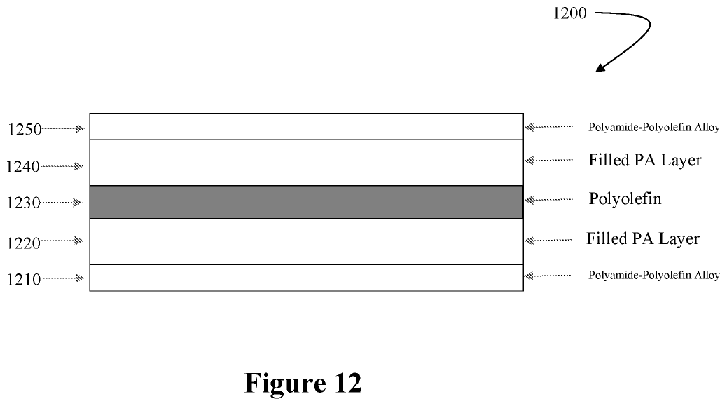

Turning now to FIG. 12, there is shown a cross sectional schematic of an embodiment of backsheet 1200. Backsheet 1200 may comprise exterior layer 1210 having inner and outer surfaces, exterior intermediate layer 1220 having inner and outer surfaces, middle layer 1230 having inner and outer surfaces, interior intermediate layer 1240 having inner and outer surfaces, and interior layer 1250 having inner and outer surfaces.

In one embodiment of backsheet 1200, the outer surface of middle layer 1230 may be adjoined, adhered, or affixed to the inner surface of intermediate exterior layer 1220, and the inner surface of middle layer 1230 may be adjoined, adhered, or affixed to the outer surface of intermediate interior layer 1240. The inner surface of exterior layer 1210 may be adjoined, adhered, or affixed to the outer surface of intermediate exterior layer 1220, and the outer surface of interior layer 1250 may be adjoined, adhered, or affixed to the inner surface of intermediate interior layer 1240.

Backsheet 1200 may be adjoined, adhered, or affixed to a solar panel module by adjoining, adhering, or affixing the inner surface of interior layer 1250 or the outer surface of exterior layer 1210 to the outer surface of the solar panel module.

In one embodiment of backsheet 1200, exterior layer 1210, exterior intermediate layer 1220, middle layer 1230, interior intermediate layer 1240, and interior layer 1250 may be adjoined, adhered, or affixed via a co-extrusion process therein eliminating the need for the use of adhesives for bonding the layers of backsheet 1200 together.

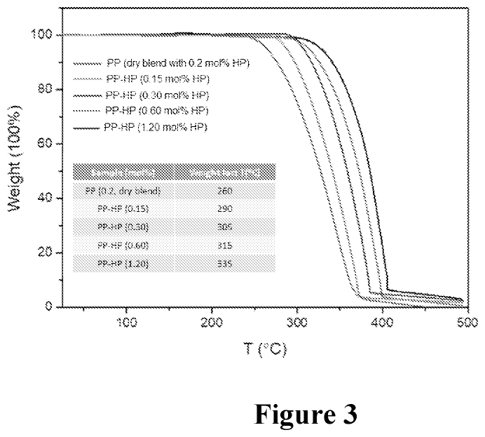

Co-extrusion processes which may be utilized for manufacturing backsheet 1200 may be similar to the co-extrusion processes shown and described in connection with FIGS. 3 and 5, except that backsheet 1200 may comprise five layers rather than the three layer construction depicted in FIGS. 3 and 7. Optimal methods employed in the co-extrusion manufacturing processes used to manufacture backsheet 1200 may vary depending upon the specific material compositions comprising the various layers of backsheet 1200, thicknesses of the various layers of backsheet 1200, as well as the temperature, pressure, dwell times, machine speed, and/or other variables associated with the specific apparatus utilized in the manufacture of backsheet 1200.

Backsheet 1200 may eliminate many of the deficiencies found in known laminated backsheets while reducing the overall cost of producing backsheet 1200. Backsheet 1200 may utilize materials which are more cost effective than fluoropolymers used in the exterior layer of known backsheets, and provide better weather resistant properties than those of PET. Moreover, certain embodiments of backsheet 1200 may be made with no interlayer adhesives.

In yet another embodiment of backsheet 1200, exterior layer 1210 and interior layer 1250 of backsheet 1200 may comprise a polyamide-polyolefin alloy, each of which layers may have a thickness of between about 1.0 mil and about 4.0 mils. The polyolefin component in this material, which replaces the ionomer component in other embodiments (such as the embodiment depicted in FIG. 6), contains multiple polar functionalities which are segments of the polyolefin molecules themselves. Such polar functionalities may include hindered phenol antioxidants, hydroxyl groups, UV-resistant chemistries, and maleic anhydride species.

These polar functionalities may be engineered and/or produced by the raw material supplier through simultaneous chemical attachment directly to the polyolefin chains during polymerization or through reactive extrusion. The resulting multi-functional polyolefins may exhibit unique properties beyond existing similarly modified polyolefins. These properties may include, but are not limited to, stability to UV radiation, thermal stability, and resistance to organic solvents.

One or more of exterior intermediate layer 1220 and interior intermediate layer 1240 may comprise a talc filled polyamide (hereinafter “PA”). PA610, PA612, PA11, PA12, PA9T, PA6, PA6G, and PA66 all may be acceptable alternative materials to be used for one or more of exterior intermediate layer 1220 and interior intermediate layer 1240. One of the materials which may be used as exterior intermediate layer 1220 and/or interior intermediate layer 1240 may comprise either PA612, due to its low cost, or PA610, due to it being a bio-based, renewable and environmentally friendly polymer material, also of relatively low cost. In one embodiment, PA610 may comprise up to about sixty-five percent (65%) renewable materials. In one such embodiment of PA610, such renewable materials may be derived from castor bean oil.

Exterior intermediate layer 1220 and interior intermediate layer 1240 may also provide excellent dielectric properties, dimensional stability and higher temperature functionality than known backsheets. The nylons can be filled between about ten percent (10%) and about forty percent (40%) with talc, with one loading being about twenty-five percent (25%).

Middle layer 1230 may comprise a polyolefin. Middle layer 1230 may also comprise a maleic anhydride species which may enhance the bonding of intermediate layers 1220 and 1240 comprising a polyamide to middle layer 1230 comprising a polyolefin during the fabrication process of backsheet 1200. The fabrication process of backsheet 1200 may comprise co-extrusion and/or lamination processes.

In one embodiment, backsheet 1200 may be produced as a 5-layer structure as illustrated in FIG. 12. In this embodiment, the backsheet structure is similar to the embodiment depicted as coextruded backsheet 100 in FIG. 6, except that polyolefin layer 1230 is added as the middle layer of backsheet 1200, surrounded on each side with filled polyamide (PA) intermediate layers 1220 and 1240. Polyolefin middle layer 1230 may have a thickness of between about 1.0 mil and about 5.0 mils. PA intermediate layers 1220 and 1240 may have thicknesses of between about 2.0 mils and about 6.0 mils each. Polyolefin middle layer 1230 may contain a maleic anhydride species for bonding of polyamide intermediate layers 1220 and 1240 to polyolefin middle layer 1230 during the fabrication process of backsheet 1200. The fabrication process of backsheet 1200 may comprise co-extrusion and/or lamination processes.

Further in this embodiment, exterior layer 1210 and interior layer 1250 may comprise a polyamide-polyolefin alloy, each of which may have a thickness of between about 1.0 mil and about 4.0 mils. Polyolefin middle layer 1230 may provide a moisture barrier capability to backsheet 600 for reduction or elimination of moisture transmission through backsheet 1200 and into the solar module to which backsheet 1200 may be adjoined, adhered, or affixed. The addition of middle layer 1230 between intermediate layers 1220 and 1240 in backsheet 1200 also maintains symmetry in backsheet 1200 which may reduce curl and may also eliminate the chance of lamination errors in solar panel module manufacturing by allowing the module manufacturer to laminate either the inner surface of interior layer 1250 or the outer surface of exterior layer 1210 to a surface of the solar panel module.

Other than the thickness of polyolefin middle layer 1230, the thicknesses of the remaining layers of backsheet 1200 may be determined by the voltage rating required for the solar panel module. Presently, “relied upon insulation” refers to materials in the backsheet that have a relative thermal index (“RTI”) of about 90° C. or higher. Generally, 1000V rated solar panel modules require backsheets, such as backsheet 1200, to maintain a relied upon minimum insulation thickness of 6.0 mil, and 1500V modules require a minimum insulation thickness of 12.0 mil. In certain embodiments of backsheet 1200, PA intermediate layers 1220 and 1240 and polyamide-polyolefin alloy exterior and interior layers 1210 and 1250 meet this requirement for relied upon insulation, however, polyolefin middle layer 1230 may not. Therefore, the layer thicknesses may be primarily driven by this requirement for relied upon insulation along with the barrier performance provided by polyolefin middle layer 1230 as a thicker polyolefin middle layer 1230 may provide a better moisture barrier. In one embodiment of backsheet 1200, the polyamide-polyolefin alloy of exterior layer 1210 and interior layer 1250 should obtain a minimum relative thermal index (RTI) of about 90° C. in order to be included in the relied upon insulation requirements.

In one embodiment of backsheet 1200, the alloy material making up exterior and interior layers 1210 and 1250 of the 5-layer structure of FIG. 12 comprises a polyamide-polyolefin alloy. The polyolefin component in this material, which may replace the ionomer component in other embodiments, may contain multiple polar functionalities which are segments of the polyolefin molecules themselves. Said functionalities may include hindered phenol antioxidants, hydroxyl groups, UV-resistant chemistries, and maleic anhydride species. These functionalities may be produced at the raw material supplier through simultaneous chemical attachment directly to the polyolefin chains during polymerization or through reactive extrusion. The resulting multi-functional polyolefins may exhibit unique properties beyond existing similarly modified polyolefins. These properties may include, but are not limited to, stability to UV radiation, thermal stability, and resistance to organic solvents. This material should obtain a minimum relative thermal index (RTI) of 90° C. in order to be included in the relied upon insulation requirements. The thickness of the polyamide-polyolefin alloy layers may be between about 1.0 and about 4.0 mils.

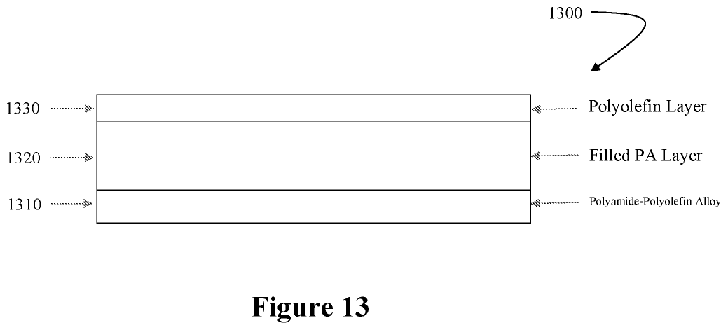

Turning now to FIG. 13, there is shown a cross sectional schematic of an embodiment of backsheet 1300. Backsheet 1300 may comprise exterior layer 1310 having inner and outer surfaces, middle layer 1320 having inner and outer surfaces, and interior layer 1330 having inner and outer surfaces.

In this embodiment of backsheet 1300, the outer surface of middle layer 1320 may be adjoined, adhered, or affixed to the inner surface of exterior layer 1310, and the inner surface of middle layer 1320 may be adjoined, adhered, or affixed to the outer surface of interior layer 1330. In one embodiment, exterior layer 1310, middle layer 1320, and interior layer 1330 may be adjoined, adhered, or affixed via a co-extrusion process therein eliminating the need for the use of adhesives for bonding the layers of backsheet 1300 together.

Co-extrusion processes which may be utilized for manufacturing backsheet 1300 may be similar to the co-extrusion processes shown and described in connection with FIGS. 5 and 7, except that backsheet 1300 may comprise different material compositions utilized in the layered construction of backsheet 1300. Optimal methods employed in the co-extrusion manufacturing processes used to manufacture backsheet 1300 may vary depending upon the specific material compositions comprising the various layers of backsheet 1300, thicknesses of the various layers of backsheet 1300, as well as the temperature, pressure, dwell times, machine speed, and/or other variables associated with the specific apparatus utilized in the manufacture of backsheet 1300.

Backsheet 1300 may eliminate many of the deficiencies found in known laminated backsheets while reducing the overall cost of producing backsheet 1300. Backsheet 1300 may utilize materials which are more cost effective than fluoropolymers used in the exterior layer of known backsheets, and provide better weather resistant properties than those of PET. Moreover, backsheet 1300 may be made with no interlayer adhesives.

In yet another embodiment of backsheet 1300, exterior layer 1310 of backsheet 1300 may comprise a polyamide-polyolefin alloy, which layer may have a thickness of between about 1.0 mil and about 4.0 mils. The polyolefin component in this material, which replaces the ionomer component in other embodiments (such as the embodiment depicted in FIG. 7), contains multiple polar functionalities which are segments of the polyolefin molecules themselves. Such polar functionalities may include hindered phenol antioxidants, hydroxyl groups, UV-resistant chemistries, and maleic anhydride species.

These polar functionalities may be engineered and/or produced by the raw material supplier through simultaneous chemical attachment directly to the polyolefin chains during polymerization or through reactive extrusion. The resulting multi-functional polyolefins may exhibit unique properties beyond existing similarly modified polyolefins. These properties may include, but are not limited to, stability to UV radiation, thermal stability, and resistance to organic solvents.

Middle layer 1320 may comprise a talc filled polyamide (hereinafter “PA”). PA610, PA612, PA11, PA12, PA9T, PA6, PA6G, and PA66 all may be acceptable alternative materials to be used for middle layer 1320. One of the materials which may be used as middle layer 1320 may comprise either PA612, due to its low cost, or PA610, due to it being a bio-based, renewable and environmentally friendly polymer material, also of relatively low cost. In one embodiment, PA610 may comprise up to about sixty-five percent (65%) renewable materials. In one such embodiment of PA610, such renewable materials may be derived from castor bean oil.

Interior layer 1330 may comprise a polyolefin. Interior layer 1330 may also comprise a maleic anhydride species which may enhance the bonding of middle layer 1320 comprising a polyamide to inner layer 1330 comprising a polyolefin during the fabrication process of backsheet 1300. The fabrication process of backsheet 1300 may comprise co-extrusion and/or lamination processes.

In one embodiment, backsheet 1300 may be produced as a 3-layer structure as illustrated in FIG. 13. In this embodiment, interior layer 1330, having an inner surface and an outer surface, may comprise a polyolefin layer. The inner surface of interior layer 1330 may be adjoined, adhered, or affixed to an outer surface of an encapsulant layer of a solar panel module. Interior layer 1330 may have a thickness of between about 1.0 mil and about 5.0 mil.

Also in this embodiment, middle layer 1320, having an inner surface and an outer surface, may comprise a polyamide layer and have a thickness of between about 4.0 mil and about 12 mil, depending upon the rating requirement of the solar panel module with which backsheet 1300 will be adjoined, adhered, or affixed.

Also, in this embodiment, exterior layer 1310, having an inner surface and an outer surface, may comprise a polyamide-polyolefin alloy layer and have a thickness of between about 1.0 and about 4.0 mils. The configuration of this embodiment of backsheet 1300 may be designed to reduce distortion of the various backsheet 1300 layers during the lamination process caused by the potentially high shrinkage of the encapsulant layer used in the solar panel module to which backsheet 1300 is adjoined, adhered, or affixed.

In certain embodiments of the 3-layer design of backsheet 1300, a reduction and/or elimination of lamination defects (sometimes experienced with certain embodiments of the 5-layer backsheet 1200 design) may be realized. Such defects may be caused by shifting of a low-modulus interior layer 1230 and higher modulus outer layers, such as middle layer 1220 and/or exterior layer 1210, at temperatures seen by backsheet 1200 when being laminated to a solar panel module. Nevertheless, 5-layer backsheet 1200 embodiments are still suitable for defect-free laminations when a low-shrinkage solar panel module encapsulant is used in the lamination process.

Other than the thickness of polyolefin middle layer 1320, the thicknesses of the remaining layers of backsheet 1300 may be determined by the voltage rating required for the solar panel module. Presently, “relied upon insulation” refers to materials in the backsheet that have a relative thermal index (“RTI”) of about 90° C. or higher. Generally, 1000V rated solar panel modules require backsheets, such as backsheet 1300, to maintain a relied upon minimum insulation thickness of 6.0 mil, and 1500V modules require a minimum insulation thickness of 12.0 mil. In certain embodiments of backsheet 1300, polyamide-polyolefin alloy exterior layer 1310 and polyolefin interior layer 1330 meet this requirement for relied upon insulation, however, polyolefin middle layer 1320 may not. Therefore, the layer thicknesses may be primarily driven by this requirement for relied upon insulation along with the barrier performance provided by polyolefin middle layer 1320 as a thicker polyolefin middle layer 1320 may provide a better moisture barrier. In one embodiment of backsheet 1300, the polyamide-polyolefin alloy of exterior layer 1310 should obtain a minimum relative thermal index (“RTI”) of about 90° C. in order to be included in the relied upon insulation requirements.

In one embodiment of backsheet 1300, the alloy material making up exterior layer 1310 of the 3-layer structure of FIG. 13 comprises a polyamide-polyolefin alloy. The polyolefin component in this material, which may replace the ionomer component in other embodiments, may contain multiple polar functionalities which are segments of the polyolefin molecules themselves. Said functionalities may include hindered phenol antioxidants, hydroxyl groups, UV-resistant chemistries, and maleic anhydride species. These functionalities may be produced at the raw material supplier through simultaneous chemical attachment directly to the polyolefin chains during polymerization or through reactive extrusion. The resulting multi-functional polyolefins may exhibit unique properties beyond existing similarly modified polyolefins. These properties may include, but are not limited to, stability to UV radiation, thermal stability, and resistance to organic solvents. This material should obtain a minimum relative thermal index (RTI) of 90° C. in order to be included in the relied upon insulation requirements. The thickness of the polyamide-polyolefin alloy layer may be between about 1.0 and about 4.0 mils.

Hindered Phenol Polyolefins as the Entire Backsheet Structure

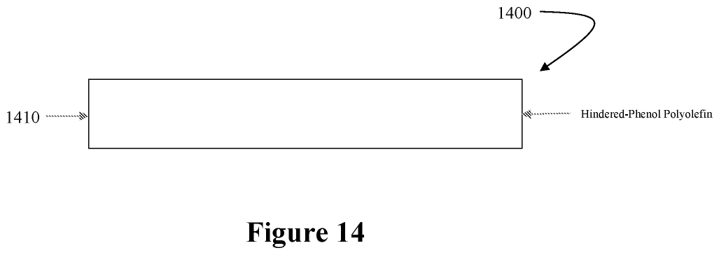

Turning now to FIG. 14, there is shown a cross sectional schematic of an embodiment of backsheet 1400. In one embodiment, backsheet 1400 may comprise a single layer or monolayer backsheet construction comprising monolayer 1410 having inner and outer surfaces.

In this embodiment of backsheet 1400, the inner surface of monolayer 1410 may be adjoined, adhered, or affixed to an outer surface of an encapsulant layer of a solar panel module. monolayer 1410 may have a thickness of between about 6.0 mil and about 20.0 mil.

Backsheet 1400 may eliminate many of the deficiencies found in known backsheets while reducing the overall cost of producing backsheet 1400. Backsheet 1400 may utilize materials which are more cost effective than fluoropolymers used in known backsheets, and provide better weather resistant properties than those of PET. Moreover, backsheet 1400 may be made with no interlayer adhesives.

In yet another embodiment of backsheet 1400, monolayer 1410 of backsheet 1400 may comprise a polyolefin such as Hindered-Phenol Polyolefin which layer may have a thickness of between about 6.0 mil and about 20.0 mils. The polyolefin component in this material contains multiple polar functionalities which are segments of the polyolefin molecules themselves. Such polar functionalities may include hindered phenol antioxidants, hydroxyl groups, UV-resistant chemistries, and maleic anhydride species.

These polar functionalities may be engineered and/or produced by the raw material supplier through simultaneous chemical attachment directly to the polyolefin chains during polymerization or through reactive extrusion. The resulting multi-functional polyolefins may exhibit unique properties beyond existing similarly modified polyolefins. These properties may include, but are not limited to, stability to UV radiation, thermal stability, and resistance to organic solvents.

In one embodiment, backsheet 1400 may be produced as a single layer structure as illustrated in FIG. 14. In this embodiment, monolayer 1410, having an inner surface and an outer surface, may comprise a polyolefin layer. The inner surface of monolayer 1410 may be adjoined, adhered, or affixed to an outer surface of an encapsulant layer of a solar panel module. Monolayer 1410 may have a thickness of between about 6.0 mil and about 20.0 mil.

The thicknesses of the monolayer of backsheet 1400 may be determined by the voltage rating required for the solar panel module. Presently, “relied upon insulation” refers to materials in the backsheet that have a relative thermal index (“RTI”) of about 90° C. or higher. Generally, 1000V rated solar panel modules require backsheets, such as backsheet 1400, to maintain a relied upon minimum insulation thickness of 6.0 mil, and 1500V modules require a minimum insulation thickness of 12.0 mil. In certain embodiments of backsheet 1400, polyolefin (such as Hindered-Phenol Polyolefin) monolayer 1410 may meet this requirement for relied upon insulation. The layer thicknesses may be primarily driven by this requirement for relied upon insulation along with the barrier performance provided by polyolefin monolayer 1410. In one embodiment of backsheet 1400, the polyamide monolayer 1410 should obtain a minimum relative thermal index (“RTI”) of about 90° C. in order to be included in the relied upon insulation requirements.

In one embodiment of backsheet 1400, a monolayer backsheet structure such as monolayer 1410 may be produced using a Hindered-Phenol Polyolefin in the construction. The polyolefin may contain multiple polar functionalities which are segments of the polyolefin molecules themselves. Said functionalities may include hindered phenol antioxidants, hydroxyl groups, UV-resistant chemistries, and maleic anhydride species. These functionalities may be produced at the raw material supplier through simultaneous chemical attachment directly to the polyolefin chains during polymerization or through reactive extrusion. The resulting multi-functional polyolefins may exhibit unique properties beyond existing similarly modified polyolefins. These properties may include, but are not limited to, stability to UV radiation, thermal stability, and resistance to organic solvents. This construction may provide proper bonding to the solar module encapsulant of choice and may contain all of the necessary functionalities in a single layer backsheet such as backsheet 1400.

In certain embodiments of backsheet 1400, monolayer 1410 may comprise a polyolefin, such as a Hindered-Phenol Polyolefin, and a maleic anhydride. Inclusion of a maleic anhydride in monolayer 1410 may promote adhesion of backsheet 1400 to a solar panel module encapsulant.

In one embodiment of backsheet 1400, polyolefin layer 1410 should obtain a relative thermal index (“RTI”) of 90° C. or higher in order to meet relied upon insulation requirements for solar modules. Presently, the minimum thickness of RTI rated material is 6.0 mil for 1000V modules and 12.0 mil for 1500V modules. Therefore, the total thickness of one embodiment of backsheet 1400 may be between about 6.0 mil and about 20.0 mil, depending upon the voltage rating of the solar module.

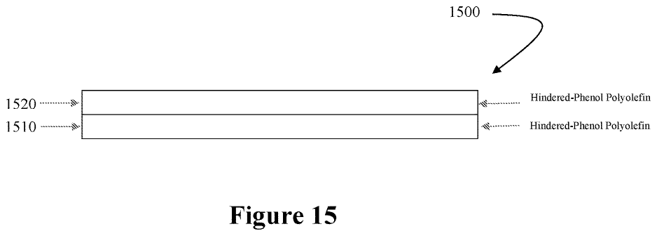

Turning now to FIG. 15, there is shown a cross sectional schematic of an embodiment of backsheet 1500. In one embodiment, backsheet 1500 may comprise a multi-layer backsheet construction comprising exterior layer 1510 having inner and outer surfaces, and interior layer 1520 having inner and outer surfaces.

In an embodiment of backsheet 1500, the outer surface of interior layer 1520 may be adjoined, adhered, or affixed to the inner surface of exterior layer 1510. In one embodiment of backsheet 1500, exterior layer 1510 and interior layer 1520 may be adjoined, adhered, or affixed via a co-extrusion process therein eliminating the need for the use of adhesives for bonding the layers of backsheet 1500 together.

Co-extrusion processes which may be utilized for manufacturing backsheet 1500 may be similar to the co-extrusion processes shown and described in connection with FIGS. 3 and 5, except that backsheet 1500 may comprise different material compositions utilized in the layered construction of backsheet 1500. Optimal methods employed in the co-extrusion manufacturing processes used to manufacture backsheet 1500 may vary depending upon the specific material compositions comprising the various layers of backsheet 1500, thicknesses of the various layers of backsheet 1500, as well as the temperature, pressure, dwell times, machine speed, and/or other variables associated with the specific apparatus utilized in the manufacture of backsheet 1500.

Backsheet 1500 may eliminate many of the deficiencies found in known laminated backsheets while reducing the overall cost of producing backsheet 1500. Backsheet 1500 may utilize materials which are more cost effective than fluoropolymers used in the exterior layer of known backsheets, and provide better weather resistant properties than those of PET. Moreover, backsheet 1500 may be made with no interlayer adhesives.

In yet another embodiment of backsheet 1500, exterior layer 1510 and interior layer 1520 of backsheet 1500 may each comprise a polyolefin, such as Hindered-Phenol Polyolefin, which layers may have a combined total thickness of between about 6.0 mil and about 20.0 mils. The polyolefin component in this material contains multiple polar functionalities which are segments of the polyolefin molecules themselves. Such polar functionalities may include hindered phenol antioxidants, hydroxyl groups, UV-resistant chemistries, and maleic anhydride species.

These polar functionalities may be engineered and/or produced by the raw material supplier through simultaneous chemical attachment directly to the polyolefin chains during polymerization or through reactive extrusion. The resulting multi-functional polyolefins may exhibit unique properties beyond existing similarly modified polyolefins. These properties may include, but are not limited to, stability to UV radiation, thermal stability, and resistance to organic solvents.

In one embodiment, backsheet 1500 may be produced as a two-layer structure as illustrated in FIG. 15. In this embodiment, exterior layer 1510, having an inner surface and an outer surface, and internal layer 1520, having an inner surface and an outer surface, may each comprise a polyolefin layer. In certain embodiments, one or more of the polyolefin layers of backsheet 1500 may comprise a Hindered-Phenol Polyolefin. The inner surface of exterior layer 1510 may be adjoined, adhered, or affixed to an outer surface of interior layer 1520 via a co-extrusion process therein eliminating the need for the use of adhesives for bonding the layers of backsheet 1500 together.

In certain embodiments of backsheet 1500, the inner surface of interior layer 1520 may be adjoined, adhered, or affixed to an outer surface of an encapsulant layer of a solar panel module.

In certain embodiments of backsheet 1500, one or more of exterior and interior layers 1510 and 1520 may comprise a polyolefin. Such polyolefin layers may contain multiple polar functionalities which are segments of the polyolefin molecules themselves. Such functionalities may include hindered phenol antioxidants, hydroxyl groups, UV-resistant chemistries, and maleic anhydride species. These functionalities may be produced at the polyolefin material supplier through simultaneous chemical attachment directly to the polyolefin chains during polymerization or through reactive extrusion. The resulting multi-functional polyolefins may exhibit unique properties beyond existing similarly modified polyolefins. These properties may include, but are not limited to, stability to UV radiation, thermal stability, and resistance to organic solvents. This polyolefin construction may provide proper bonding to the solar module encapsulant of choice and may contain all of the necessary functionalities in a multiple layer backsheet such as backsheet 1500.

In another embodiment of backsheet 1500, at least a portion of exterior layer 1510 may comprise titanium, and at least a portion of interior layer 1520 may comprise carbon black. In yet another embodiment of backsheet 1500, exterior layer 1510 may comprise up to about fifteen percent (15%) titanium, and interior layer 1520 may comprise up to about fifteen percent (15%) carbon black. The result of such compositions may be the a backsheet 1500 construction having black and white sides of backsheet 1500. In certain embodiments, interior layer 1520 comprises the black side of backsheet 1500, while exterior layer 1510 comprises the white side of backsheet 1500. In certain embodiments, the black side provides an aesthetic color and/or light absorbing quality to interior layer 1520, and/or the white side provides a cooling and/or light reflective quality to exterior layer 1510.

The thicknesses of the layers of backsheet 1500 may be determined by the thermal and/or voltage rating required for the solar panel module. Presently, “relied upon insulation” refers to materials in the backsheet that have a relative thermal index (“RTI”) of about 90° C. or higher. Generally, 1000V rated solar panel modules require backsheets, such as backsheet 1500, to maintain a relied upon minimum insulation thickness of 6.0 mil, and 1500V modules require a minimum insulation thickness of 12.0 mil. In certain embodiments of backsheet 1500, polyolefin exterior layer 1510 and polyolefin interior layer 1520 meet this requirement for relied upon insulation. Therefore, the various layer thicknesses may be primarily driven by the RTI and/or voltage rating of the solar panel module to which backsheet 1500 is adjoined, adhered, or affixed. In one embodiment of backsheet 1500, the layers of backsheet 1500 should obtain a minimum relative thermal index (“RTI”) of about 90° C. in order to be in compliance with the relied upon insulation requirements.

In certain embodiments of backsheet 1500, interior layer 1520 may comprise a polyolefin, such as a Hindered-Phenol Polyolefin, and a maleic anhydride. Inclusion of a maleic anhydride in at least interior layer 1520 may promote adhesion of backsheet 1500 to a solar panel module encapsulant. In certain embodiments of backsheet 1500, maleic anhydride may not be included in exterior layer 1510 which may save costs in a multi-layer backsheet construction where only interior layer 1520 comprises a maleic anhydride.

In certain embodiments of backsheet 1500, a multi-layer structure may be produced comprising a Hindered-Phenol Polyolefin material such as the Hindered-Phenol Polyolefin described above. There may be certain advantages to a multi-layer structure using this polymer. Such advantages may include, but are not limited to, the following:

The incorporation of up to about 15% carbon black in one layer and up to about 15% titanium dioxide in an additional layer in order to produce a backsheet construction with both a “black” and “white” side. The advantage of this design is to provide an aesthetically pleasing “black” color on the cell-side of the module, and a cooling “white” layer on the back-facing side of the module.

The incorporation of a maleic anhydride species in only the “interior” layer of the backsheet to promote adhesion to a solar panel module encapsulant. In certain embodiments, maleic anhydride may not be needed on the backside of the backsheet and therefore, creating a two-layer construction may save costs.

The disclosure herein is directed to the variations and modifications of the elements and methods of the invention disclosed and that will be apparent to those skilled in the art in light of the disclosure herein. Thus, it is intended that the present invention covers the modifications and variations of this invention, provided those modifications and variations come within the scope of the appended claims and the equivalents thereof.

What is claimed is:

1. A photovoltaic solar panel backsheet comprising:
an exterior layer having inner and outer surfaces, said exterior layer comprising a polyamide-polyolefin alloy;
an intermediate exterior layer having inner and outer surfaces;
a middle layer, having inner and outer surfaces said middle layer comprising a polyolefin;
an intermediate interior layer having inner and outer surfaces; and
an interior layer having inner and outer surfaces, said interior layer comprising a polyamide-polyolefin alloy;
wherein said outer surface of said middle layer is adjoined to said inner surface of said intermediate exterior layer, said inner surface of said middle layer is adjoined to said outer surface of said intermediate interior layer, said inner surface of said exterior layer is adjoined to said outer surface of said intermediate exterior layer, and said outer surface of said interior layer is adjoined to said inner surface of said intermediate interior layer.

2. The photovoltaic solar panel backsheet of claim 1, wherein said exterior intermediate layer comprises at least one of PA610, PA612, PA11, PA12, PA9T, PA6, PA6G, and PA66.

3. The photovoltaic solar panel backsheet of claim 1, wherein said interior intermediate layer comprises at least one of PA610, PA612, PA11, PA12, PA9T, PA6, PA6G, and PA66.

4. A photovoltaic solar panel backsheet comprising:
an exterior layer having inner and outer surfaces, said exterior layer comprising a polyamide-polyolefin alloy;
a middle layer, having inner and outer surfaces, said middle layer comprising a filled PA; and
an interior layer having inner and outer surfaces, said interior layer comprising a polyolefin;
wherein said outer surface of said middle layer is adjoined to said inner surface of said exterior layer, and said inner surface of said middle layer is adjoined to said outer surface of said interior layer.

5. The photovoltaic solar panel backsheet of claim 4, wherein said middle layer comprises at least one of PA610, PA612, PA11, PA12, PA9T, PA6, PA6G, and PA66.

6. A photovoltaic solar panel module comprising:
a front cover having inner and outer surfaces;
one or more photovoltaic cells substantially encapsulated in an encapsulant having a top outer surface and a bottom outer surface;
a backsheet comprising: an exterior layer having inner and outer surfaces, an exterior intermediate layer having inner and outer surfaces and comprising a polyamide, a middle layer having inner and outer surfaces and comprising a polyolefin, interior intermediate layer having inner and outer surfaces and comprising a polyamide, and an interior layer having inner and outer surfaces; wherein said outer surface of said middle layer is adjoined to said inner surface of said intermediate exterior layer, said inner surface of said middle layer is adjoined to said outer surface of said intermediate interior layer, said inner surface of said exterior layer is adjoined to said outer surface of said intermediate exterior layer, and said outer surface of said interior layer is adjoined to said inner surface of said intermediate interior layer; and
wherein said top outer surface of said encapsulant is adjoined to said inner surface of said front cover, and said bottom outer surface of said encapsulant is adjoined to said inner surface of said interior layer of said backsheet.

7. The photovoltaic solar panel module of claim 6, wherein said exterior layer comprises a polyamide and ionomer alloy, and said interior layer comprises a polyamide and ionomer alloy.

8. The photovoltaic solar panel module of claim 6, wherein said exterior layer comprises a polyamide-polyolefin alloy, and said interior layer comprises a polyamide-polyolefin alloy.

9. A photovoltaic solar panel module comprising:
a front cover having inner and outer surfaces;
one or more photovoltaic cells substantially encapsulated in an encapsulant having a top outer surface and a bottom outer surface;
a backsheet comprising: an exterior layer having inner and outer surfaces; a middle layer, having inner and outer surfaces and comprising a polyamide; and an interior layer having inner and outer surfaces and comprising a polyolefin; wherein said outer surface of said middle layer may be adjoined to said inner surface of said exterior layer, and said inner surface of said middle layer may be adjoined to said outer surface of said interior layer; and
wherein said top outer surface of said encapsulant is adjoined to said inner surface of said front cover, and said bottom outer surface of said encapsulant is adjoined to said inner surface of said interior layer of said backsheet.

10. The photovoltaic solar panel module of claim 9, wherein said exterior layer comprises a polyamide and ionomer alloy.

11. The photovoltaic solar panel module of claim 9, wherein said exterior layer comprises a polyamide-polyolefin alloy.

12. A photovoltaic solar panel module comprising:
a front cover having inner and outer surfaces;
one or more photovoltaic cells substantially encapsulated in an encapsulant having a top outer surface and a bottom outer surface;
a mono-layer backsheet having inner and outer surfaces comprising Hindered-Phenol Polyolefin; and
wherein said top outer surface of said encapsulant is adjoined to said inner surface of said backsheet.

13. A photovoltaic solar panel backsheet comprising:
an exterior layer having inner and outer surfaces, said exterior layer comprising a Hindered-Phenol Polyolefin; and
an interior layer having inner and outer surfaces, said interior layer comprising a Hindered-Phenol Polyolefin;
wherein said outer surface of said interior layer is adjoined to said inner surface of said exterior layer.
